(19) United States
(12) Patent Application Publication
(10) Pub. No.: US 2003/0088384 A1
(43) Pub. Date: May 8, 2003

(54) Chemical substance classification apparatus, chemical substance classification method, and program

(75) Inventors: Gen Hori, Wako-shi (JP); Hiroyuki Nakahara, Wako-shi (JP); Shinichi Nishimura, Wako-shi (JP); Masato Inoue, Wako-shi (JP)

Correspondence Address: COHEN, PONTANI, LIEBERMAN & PAVANE, 551 FIFTH AVENUE, SUITE 1210, NEW YORK, NY, 10176, US

(73) Assignee: Riken

(21) Appl. No.: 10/287,201

(22) Filed: Nov. 4, 2002

(30) Foreign Application Priority Data
Nov. 5, 2001 (JP) 2001-339396

(51) Int. Cl. H03F 1/26; H04B 15/00; G06F 15/00

(52) U.S. Cl. 702/189

(57) ABSTRACT

An information reception unit of a chemical substance classification apparatus receives plural kinds of target change information on changes in a quantity of a plurality of chemical substances, applies a predetermined conversion to the target change information, and supplies them to a component analysis unit as a target signal group. The component analysis unit analyzes independent components of the target signal group by independent component analysis, and outputs a component signal group as the analysis result. An analogousness degree calculation unit applies a predetermined inversion to the component signal group, regards the inversion result as a plural kinds of component change information, and calculates analogousness degrees of each component change information with respect to each of the plural kinds of target change information. A classification unit classifies the plural kinds of target change information into a plurality of groups based on analogousness degrees calculated by the analogousness degree calculation unit.

### BACKGROUND OF THE INVENTION

1. Field of the Invention

The present invention relates to a chemical substance classification apparatus, a chemical substance classification method, and a program.

2. Description of the Related Art

Conventionally, in the field of genetic study, techniques for computer-based analysis of genetic information using DNA chips (DNA microarrays) have been attracting attention. In the field of DNA chips, DNA fixed on a substrate is hybridized with another DNA or RNA marked with a fluorescent material, etc., its image is taken by a detector, and information on expression of the DNA or RNA is obtained. Other than this, attempts have been made to obtain information on change in the density of proteins and utilize the obtained information in biological researches.

Information obtained from a DNA chip shows how quantities (density, etc.) of a chemical substance corresponding to each DNA change in accordance with some experimental conditions (lapse of time, etc.).

There have also been made attempts to analogize functions of DNAs whose functions are yet unknown, by classifying the DNAs based on other DNAs whose functions have been elucidated.

However, in conventional classification of DNAs, human labor has been generally employed in order to classify analogousness of changes in quantities of a chemical substance corresponding to each DNA, using empirical rule or heuristic methods.

Thus, there has been demanded a method of classifying information on changes in quantities of a chemical substance into a group analogous to it, as precise as possible and automatically, with the use of a computer.

The present invention was made to solve the above problems. Thus, an object of the present invention is to provide a chemical substance classification apparatus and a chemical substance classification method suitable for classifying information on changes in a quantity of chemical substances with precision, and a program for realizing those apparatus and method

### SUMMARY OF THE INVENTION

To achieve the above object, the following invention is to be disclosed, in accordance with the principle of the present invention.

A chemical substance classification apparatus according to a first aspect of the present invention classifies plural kinds of information (hereinafter referred to as change information) on changes in a quantity of a plurality of chemical substances (including genes and genetic products), and comprises: an information reception unit; a component analysis unit; an analogousness degree calculation unit; and a classification unit, each of which is structured as follows:

the information reception unit receives plural kinds of change information on changes in a quantity of a plurality of chemical substances as plural kinds of target change information, and supplies the received target change information to the component analysis unit as a target signal group corresponding to the target change information;

the component analysis unit receives the target signal group, analyzes a principal component or independent components of the target signal group in accordance with principal component analysis (PCA) or independent component analysis (ICA), and outputs a component signal group as a result of the analysis;

the analogousness degree calculation unit receives the component signal group output by the component analysis unit as plural kinds of component change information, and calculates analogousness degrees of each of the plural kinds of component change information with respect to each of the plural kinds of target change information; and

the classification unit classifies the plural kinds of target change information into a plurality of classification groups based on the analogousness degrees calculated by the analogousness degree calculation unit.

The chemical substance classification method according to the present invention may be structured as follows:

the information reception unit applies a predetermined conversion to the plural kinds of target change information, and supplies results of the conversion as the target signal group; and

the analogousness degree calculation unit applies a predetermined inversion to the component signal group, and regards results of the inversion as the plural kinds of component change information.

A chemical substance classification apparatus according to a second aspect of the present invention classifies plural kinds of information (hereinafter referred to as change information) on changes in a quantity of a plurality of chemical substances (including genes and genetic products), and comprises: a component analysis unit; an information reception unit; an analogousness degree calculation unit; and a classification unit, each of which is structured as follows:

the component analysis unit receives a target signal group including M(1≦M) kinds of signals x₁(t), x₂(t), . . . , x_{M}(t) (1≦t≦T, t and T are integers), and outputs a matrix W_{k,i} (1≦i≦M, 1≦k≦N) which is obtained when applying independent component analysis (ICA) to a component signal group including N (1≦N≦M) kinds of component signals y₁(t), y₂(t), . . . , y_{N}(t) which are independent components of the target signal group, as a result of the independent component analysis, the matrix W_{k,i} satisfying an equation

$${y}_{k} ( t ) = {\sum }_{i = 1}^{M} {W}_{k , i} {x}_{i} ( t ) ;$$

the information reception unit receives T kinds of change information on changes in a quantity of T kinds of chemical substances (including genes and genetic products) as T kinds of target change information pₜ(i) (where pₜ(i) represents change information of a case where a quantity of a t-th chemical substance changes in accordance with a change in a condition i), and supplies the received T kinds of target change information to the component analysis unit as the target signal group such that x₁(t)=pₜ(i) is satisfied;

the analogousness degree calculation unit calculates a pseudo inverse matrix W*_{i,k} of the analysis result W_{k, i} output by the component analysis unit, defines k kinds of component change information qₖ(i) which change in accordance with changes of the condition i, such that qₖ(i)=W*_{i,k} is satisfied, and calculates an analogousness degree between t-th target change information and k-th component change information when measured from an inner product of a M-dimensional vector (pₜ(1), pₜ(2), . . . , pₜ(M)) and a M-dimensional vector (qₖ(1), qₖ(2), . . . , qₖ(M)) which inner product is obtained after normalizing or weighting these vectors, or when measured from an angle formed by these vectors;

the classification unit associates each of the component change information with one of a plurality of classification groups, and classifies the t-th target change information into a classification group associated with component change information with which the t-th target change information is the most analogous by referring to the analogousness degree calculated by the analogousness degree calculation unit.

In the chemical substance classification apparatus according to the present invention, the component analysis unit may employ principal component analysis instead of the independent component analysis.

In the chemical substance classification apparatus according to the present invention, the analogousness degree calculation unit may calculate the analogousness degree between the t-th target change information and k-th component change information using yₖ(t), instead of using the inner product of the vectors obtained by normalizing or weighting, or the angle formed by the vectors.

The chemical substance classification apparatus according to the present invention may further comprise a labeling unit, which is structured as follows.

In a case where target change information predetermined for each of the plurality of classification groups is included in the classification group, the labeling unit labels the classification group with a name of a chemical substance corresponding to the predetermined target change information.

In the chemical substance classification apparatus according to the present invention, each of the plural kinds of target change information may be information representing changes in a density of RNA (including hnRNA, mRNA, and rRNA) which appears as expression of a gene, where the density changes in accordance with an experimental condition.

In the chemical substance classification apparatus according to the present invention, each of the plural kinds of target change information may be information representing changes in a density of a protein which appears as expression of a gene, where the density changes in accordance with an experimental condition.

In the chemical substance classification apparatus according to the present invention, the experimental condition may be lapse of time.

A chemical substance classification method according to a third aspect of the present invention is a method of classifying plural kinds of information (hereinafter referred to as change information) on changes in a quantity of a plurality of chemical substances (including genes and genetic products), and comprises: an information receiving step; a component analyzing step; an analogousness degree calculating step; and a classifying step, each of which is structured as follows:

in the information receiving step, plural kinds of change information on changes in a quantity of a plurality of chemical substances are received as plural kinds of target change information, and the plural kinds of target change information are supplied to the component analyzing step as a target signal group corresponding to the plural kinds of target change information;

in the component analyzing step, the target signal group is received, a principal component or independent components of the target signal group is/are analyzed by principal component analysis (PCA) or by independent component analysis (ICA), and a component signal group is output as a result of the analysis;

in the analogousness degree calculating step, the component signal group output in the component analyzing step is received as plural kinds of component change information, and analogousness degrees of each of the plural kinds of component change information with respect to each of the plural kinds of target change information are calculated; and

in the classifying step, the plural kinds of target change information received in the information receiving step are classified into a plurality of classification groups, based on the analogousness degrees calculated in the analogousness degree calculating step.

The chemical substance classification method according to the present invention may be structured as follows;

in the information receiving step, a predetermined conversion is applied to the plural kinds of target change information, and results of the conversion are supplied as the target signal group; and

in the analogousness degree calculating step, a predetermined inversion is applied to the component signal group, and results of the inversion are regarded as the plural kinds of component change information.

A chemical substance classification method according to a fourth aspect of the present invention is a method of classifying a plural kinds of information (hereinafter referred to as change information) on changes in a quantity of a plurality of chemical substances (including genes and genetic products), and comprises: a component analyzing step; an information receiving step; an analogousness degree calculating step; and a classifying step, each of which is structured as follows:

in the component analyzing step, a target signal group including M (1≦M) kinds of signals x₁(t), x₂(t), . . . , x_{M}(t) (1≦t≦T, t and T are integers) is received, and a matrix W_{k,i} (1≦i≦M, 1≦k≦N), which is obtained when applying independent component analysis (ICA) to a component signal group including N (1≦N≦M) kinds of component signals y₁(t), y₂(t), . . . , Y_{N}(t) which are independent components of the target signal group, is output as a result of the independent component analysis, the matrix W_{k,i} satisfying an equation

$${y}_{k} ( t ) = {\sum }_{i = 1}^{M} {W}_{k , i} {x}_{i} ( t ) ;$$

in the information receiving step, T kinds of change information on changes in a quantity of T kinds of chemical substances (including genes and genetic products) are received as T kinds of target change information pₜ(i) (where pₜ(i) represents change information of a case where a quantity of a t-th chemical substance changes in accordance with changes in a condition i), and the T kinds of target change information pₜ(i) are supplied to the component analyzing step as the target signal group, such that xᵢ(t)=pₜ(i) is satisfied;

in the analogousness degree calculating step, a pseudo inverse matrix W*_{i,k} of the analysis result W_{k,i} output in the component analyzing step is calculated, k kinds of component change information qₖ(i) which change in accordance with changes in the condition i are defined such that qₖ(i)=W*_{i,k} is satisfied, and an analogousness degree between t-th target change information and k-th component change information when measured from an inner product of a M-dimensional vector (pₜ(1), pₜ(2), . . . , pₜ(M)) and a M-dimensional vector (qₖ(1), qₖ(2), . . . , qₖ(M)) which inner product is obtained after normalizing or weighting these vectors, or when measured from an angle formed by theses vectors is calculated; and

in the classifying step, each of the component change information is associated with one of a plurality of classification groups, and the t-th target change information is classified into a classification group associated with component change information with which the t-th target change information is the most analogous by referring to the analogousness degree calculated in the analogousness degree calculating step.

In the chemical substance classification method according to the present invention, principal component analysis may be employed instead of the independent component analysis in the component analyzing step.

In the chemical substance classification method according to the present invention, the analogousness degree between the t-th target change information and the k-th component change information may be calculated using yₖ(t), instead of using the inner product obtained by normalizing or weighting the vectors or the angle formed by the vectors in the analogousness degree calculating step.

The chemical substance classification method according to the present invention may further comprise a labeling step, which is structured as follows.

In the labeling step, in a case where target change information predetermined for each of the plurality of classification groups is included in the classification group, the classification group is labeled with a name of a chemical substance corresponding to the predetermined target change information.

In the chemical substance classification method according to the present invention, each of the plural kinds of target change information may be information representing changes in a density of RNA (including hnRNA, mRNA, and rRNA) which appears as expression of a gene, where the density changes in accordance with an experimental condition.

In the chemical substance classification method according to the present invention, each of the plural kinds of target change information may be information representing changes in a density of a protein which appears as expression of a gene, where the density changes in accordance with an experimental condition.

In the chemical substance classification method according to the present invention, the experimental condition may be lapse of time.

A program according to a fifth aspect of the present invention controls a computer to function as the chemical substance classification apparatus described above, or controls a computer to execute the chemical substance classification method described above.

This program may be recorded on an information recording medium, thus may be distributed or sold separately from a computer, or may be directly distributed or sold to users through a computer communication network such as the Internet.

### BRIEF DESCRIPTION OF THE DRAWINGS

These objects and other objects and advantages of the present invention will become more apparent upon reading of the following detailed description and the accompanying drawings in which:

FIG. 1 is an exemplary diagram showing a schematic structure of a chemical substance classification apparatus;

FIG. 2 is a flowchart showing the steps of a chemical substance classification method;

FIG. 3 is a flowchart showing the steps of an independent component analysis process;

FIG. 4 is a flowchart showing the steps of an analogousness degree calculation process;

FIG. 5 shows graphs representing changes of genes;

FIG. 6 shows graphs representing component change information which are classification results;

FIG. 7 shows a graph representing component change information which is a classification result;

FIG. 8 shows a graph representing component change information which is a classification result;

FIG. 9 shows a graph representing component change information which is a classification result;

FIG. 10 is a diagram showing a table for comparing gene profiles and classification results; and

FIG. 11 is a diagram showing a table for comparing gene profiles and classification results.

### DETAILED DESCRIPTION OF THE PREFERRED EMBODIMENT

One embodiment of the present invention will be explained below. The embodiment to be explained below is intended for explanation, and not to limit the scope of the present invention. Accordingly, even if one with ordinary skill in the art can employ another embodiment where individual or all elements included in the present embodiment are substituted with equivalents of those, such an embodiment will be included in the scope of the present invention.

Particularly, in the following explanation, there will be explained an embodiment in which the present invention will be applied to a case where DNAs are classified based on information on changes obtained from DNA chips, for easier understanding. However, the present invention can be applied to classification of genes/genetic products such as RNAs and proteins, or chemical substances that do not originate from biological matter. Embodiments in case of classification of those matters are also included in the scope of the present invention.

Embodiment

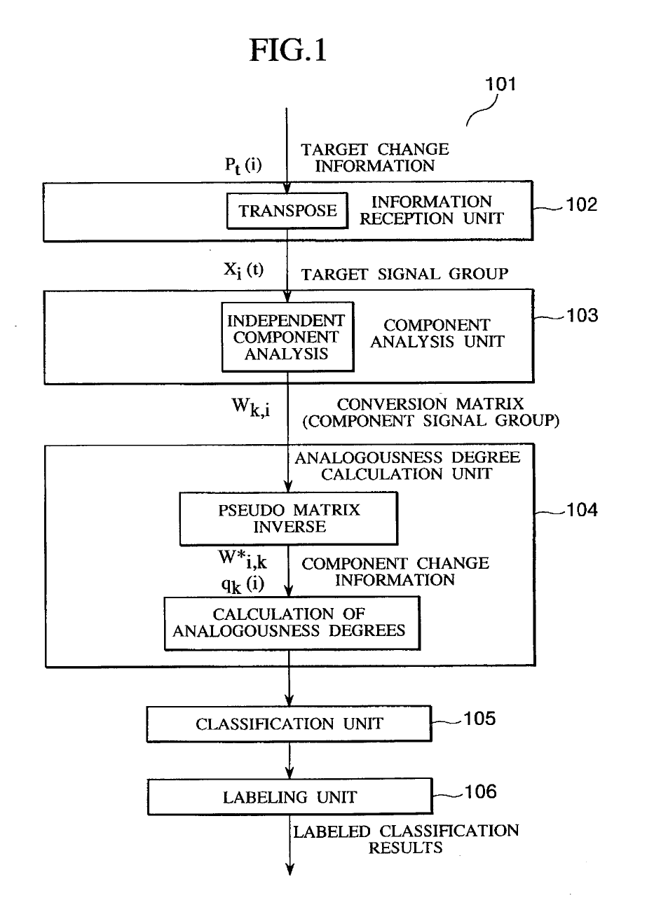

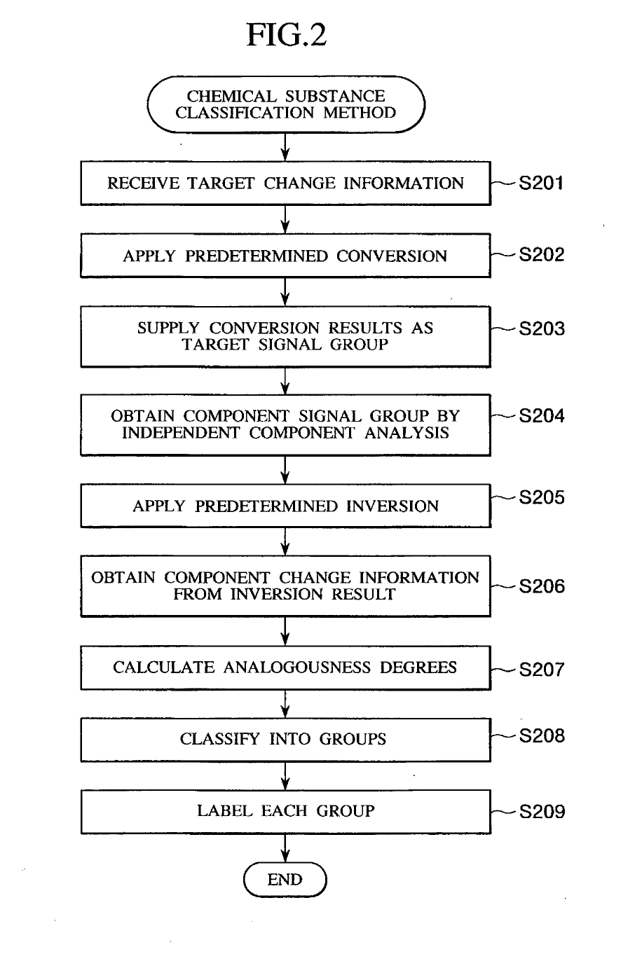

FIG. 1 is an exemplary diagram showing a schematic structure of a chemical substance classification apparatus according to the embodiment of the present invention. FIG. 2 is a flowchart showing procedures of a chemical substance classification method to be executed in the chemical substance classification apparatus. The following explanation will be made with reference to those drawings.

The chemical substance classification apparatus 101 comprises an information reception unit 102, a component analysis unit 103, an analogousness degree calculation unit 104, a classification unit 105, and a labeling unit 106. Processes to be performed by the chemical substance classification apparatus 101 will be schematically explained with reference to FIG. 1 and FIG. 2.

The information reception unit 102 receives plural pieces of information each regarding changes in a quantity of a chemical substance as inputs of plural pieces of target change information (step S201). Then, the information reception unit 102 applies a predetermined conversion to the plural pieces of target change information (step S202), and supplies the processed target change information to the component analysis unit 103 as input of a target signal group (step S203).

Then, the component analysis unit 103 receives the target signal group, analyzes independent components of the target signal group in accordance with independent component analysis (ICA), and outputs a component signal group as a result of the analysis (step S204).

In place of the independent component analysis, widely-known techniques for principal component analysis may be employed. The independent component analysis will be described later in detail.

The analogousness degree calculation unit 104 applies a predetermined inversion to the component signal group output by the component analysis unit 103 (step S205), and regards the inversion result as plural pieces of component change information (step S206). Then, the analogousness degree calculation unit calculates a degree of each component change information in terms of analogousness with each of the original target change information (step S207).

The classification unit 105 classifies the plural pieces of target change information into a plurality of groups based on the analogousness degrees calculated by the analogousness degree calculation unit 104 (step S208).

Then, in a case where specific target change information predetermined for each of the plurality of classified groups is included in this group, the labeling unit 106 labels this group with the name of a chemical substance corresponding to this predetermined target change information (step S209).

In the present embodiment, each target change information corresponds to a density of a chemical substance that appears as expression of DNA in accordance with lapse of time (experimental condition). The above-mentioned predetermined target change information corresponds to information on DNA whose expression and functions are known.

Accordingly, due to working of each unit, multiple DNAs whose functions are unknown can be automatically classified into a plurality of groups based on DNAs whose expressions are known.

Now, operations of each unit of the chemical substance classification apparatus 101 will be described more specifically.

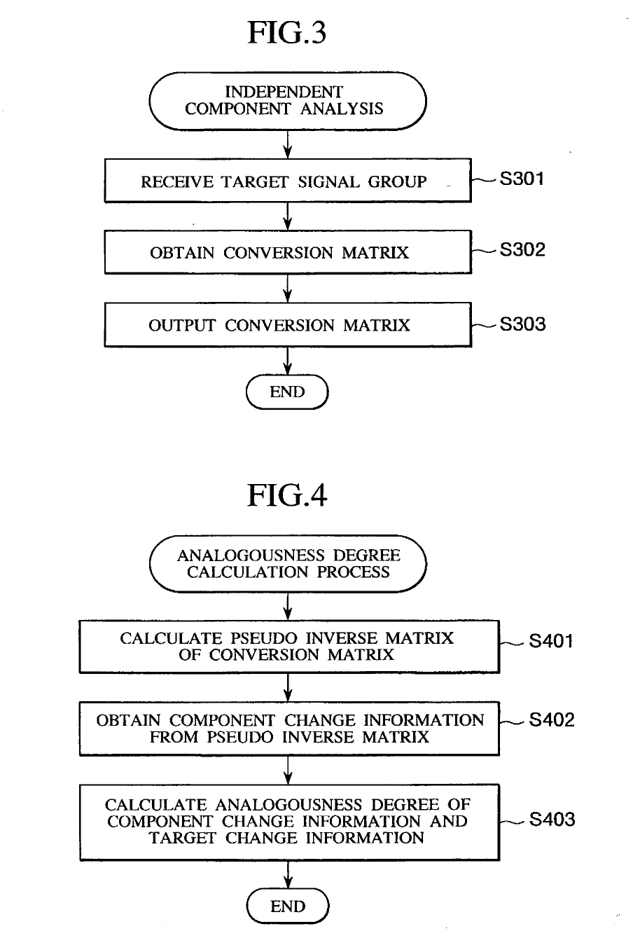

FIG. 3 is a flowchart showing steps of the independent component analysis performed by the component analysis unit 103. The operation of the component analysis unit 103 will now be explained with reference to FIG. 3.

First, the component analysis unit 103 receives input of a target signal group including M (1≦M) kinds of signals x₁(t), x₂(t), . . . , x_{M}(t) (1≦t≦T, t and T are integers) (step S301).

Then, the component analysis unit 103 applies the independent component analysis to a component signal group including N (1≦N≦M) kinds of component signals y₁(t), y₂(t), . . . , y_{N}(t) which are the independent components of the target signal group, thereby to obtain a matrix W_{k,i} (1≦i≦M, 1≦k≦N) which satisfies an equation

$${y}_{k} ( t ) = {\sum }_{i = 1}^{M} {W}_{k , i} {x}_{i} ( t )$$

(step S302).

Finally, the component analysis unit 103 outputs the matrix W_{k,i} as the result of the independent component analysis (step S303). Note that since the component signal group yₖ(t) can be obtained by calculating the product of the matrix W_{k,i} and the matrix xᵢ(t), the matrix W_{k,i} can be output as the analysis result instead of outputting the component signal group yₖ(t) as the analysis result.

The independent component analysis is one of multidimensional signal analyzing methods, and is used for obtaining a conversion formula for separating a target signal group in accordance with the independency of the target signals based on high-order statistics and temporal correlation. This conversion formula is expressed by the matrix W_{k,i}. As to the detailed calculations for obtaining this matrix, publicly known techniques can be used.

The independent component analysis is applied to the fields of BSS (Blind Source Separation) and BSD (Blind Source Deconvolution), with a single assumption that signal sources of the target signal group are independent. Achievements in those fields are to classify voices of different speakers which are uttered into a plurality of mikes, to classify electroencephalograms based on electric signals sensed at various points on a person's head, etc.

The above described independent component analysis corresponds to BSS which causes no time delay. This independent component analysis uses products of matrices. However, in case of employing BSD, the independent component analysis can be performed by using convolution instead of the products of matrices. Such an embodiment is also included in the scope of the present invention.

Now, operations of each of the units included in the chemical substance classification apparatus 101 will be explained with reference to the variables used in the operations of the component analysis unit 103.

The information reception unit 102 receives T kinds of information regarding changes in quantities of T kinds of chemical substances (including genes and genetic products), as T kinds of target change information pₜ(i) (where pₜ(i) represents information when a quantity of a t-th chemical substance changes in accordance with a change in a condition i). Then, the information reception unit 102 supplies to the component analysis unit 103, a target signal group which is obtained from the T kinds of target change information so as to satisfy xₜ(i)=pₜ(i).

This process means that a matrix pₜ(i) is converted so as to be transposed, and the obtained result is supplied to the component analysis unit 103 as a matrix xₜ(i).

FIG. 4 is a flowchart showing steps of an analogousness degree calculation process performed by the analogousness degree calculation unit 104. The following explanation will be made with reference to FIG. 4. First, the analogousness degree calculation unit 104 applies inversion to the analysis result W_{k,i} output by the component analysis unit 103, thereby to obtain a pseudo inverse matrix W*_{i,k} of this matrix W_{k,i} (step S401).

When it is assumed that the product of matrices S and R is represented by “S R”, the transposed matrix of the matrix S is represented by “S^{#}”, and the inverse matrix of the matrix S is represented by “S⁻¹”, the pseudo inverse matrix S* of the matrix S is defined as indicated below.

S*=(S^{#}S)⁻¹S^{#}

The information reception unit 102 and the analogousness degree calculation unit 104 apply such conversion and inversion to the matrices because in case of target change information obtained from DNA chips, orders of the variables are greatly different from each other in the current experimental environment such that T (changes in an experimental condition) ranges approximately from equal to or smaller than 10 to several hundreds, whereas M (number of kinds of genes) ranges from several thousands to several ten thousands. Accordingly, an embodiment in which the above conversion and inversion are not performed may be employed depending on a difference between the orders.

After obtaining the pseudo inverse matrix, the analogousness degree calculation unit 104 defines k kinds of component change information qₖ(i) which may change in accordance with changes of the condition i, such that an equation qₖ(i)=W*_{i,k} is satisfied (step S402). Each component change information qₖ(i) represents a typical change in the expression of each gene in accordance with lapse of time. Based on the component change information, the original target change information will be classified.

Then, the analogousness degree calculation unit 104 calculates an analogousness degree between t-th target change information and k-th component change information when measured from an inner product of a M-dimensional vector (pₜ(1), pₜ(2), . . . , pₜ(M)) and a M-dimensional vector (qₖ(1), qₖ(2), . . . , qₖ(M)) which inner product is obtained by normalizing or weighting these vectors, or when measured from an angle formed by these vectors (step S403).

Specifically, the following methods can be employed.

(1) To normalize the target change information and the component change information respectively, so that the averages thereof become 0 respectively, and the variances thereof become 1 respectively, then calculate the inner product of the vectors, and determine the calculated inner product as the analogousness degree. (2) To weight each component of each vector after being normalized as described in (1), multiply each component by a predetermined constant, calculate the inner product of the vectors, and determine the calculated inner product as the analogousness degree.

The greater the inner product of those vectors is, the more analogous the target change information and the component change information are.

Other than the above, an analogousness degree between t-th target change information and k-th component change information may be calculated using yₖ(t). Also in this case, the greater yₖ(t) is, the more analogous the target change information and the component change information are.

The classification unit 105 associates each of the component change information with one of a plurality of groups to make this component change information the representative of the group. Then, the classification unit 105 classifies the t-th target change information into a group which is associated with component change information with which the t-th target change information is the most analogous according to the calculation results obtained by the analogousness degree calculation unit 104. Due to this, the plural pieces of target change information are classified into a plurality of groups, respectively.

Then, in a case where specific target change information predetermined for each of the plurality of those groups is included in this group, the labeling unit 106 labels this group with the name of a chemical substance corresponding to this predetermined target change information.

### Results of Experiment

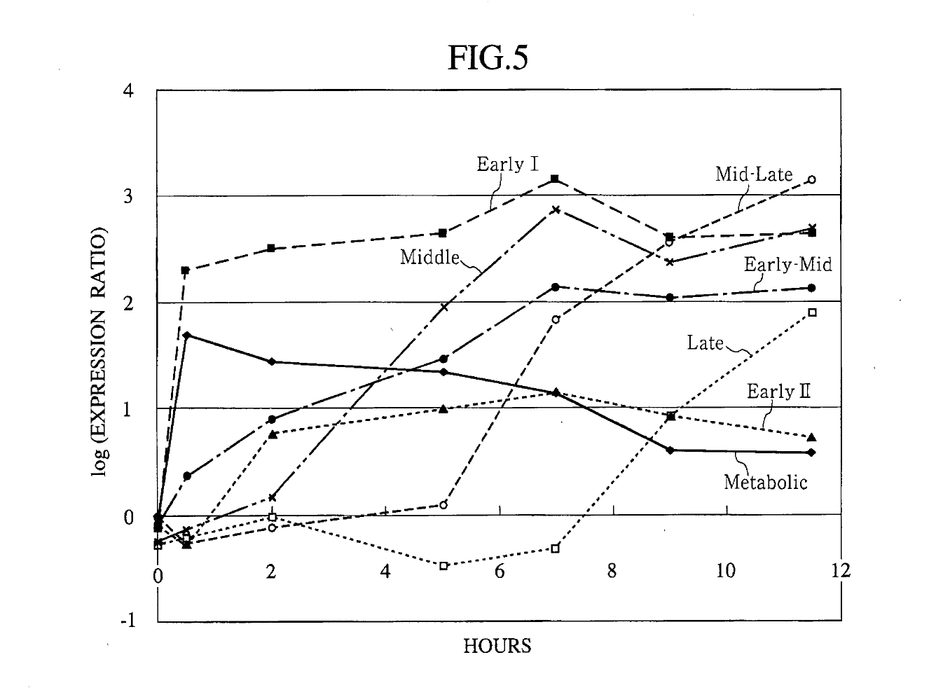

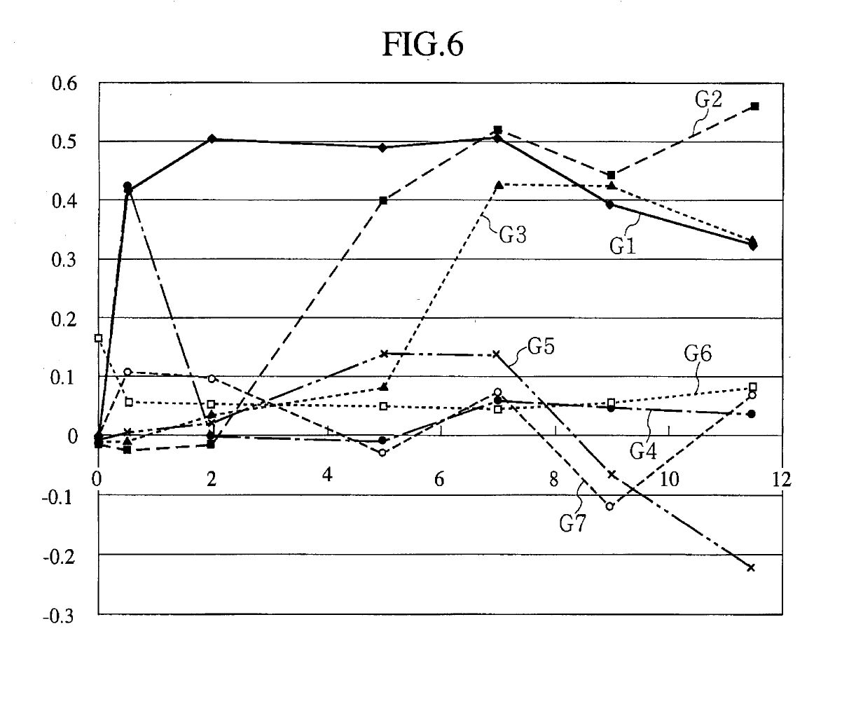

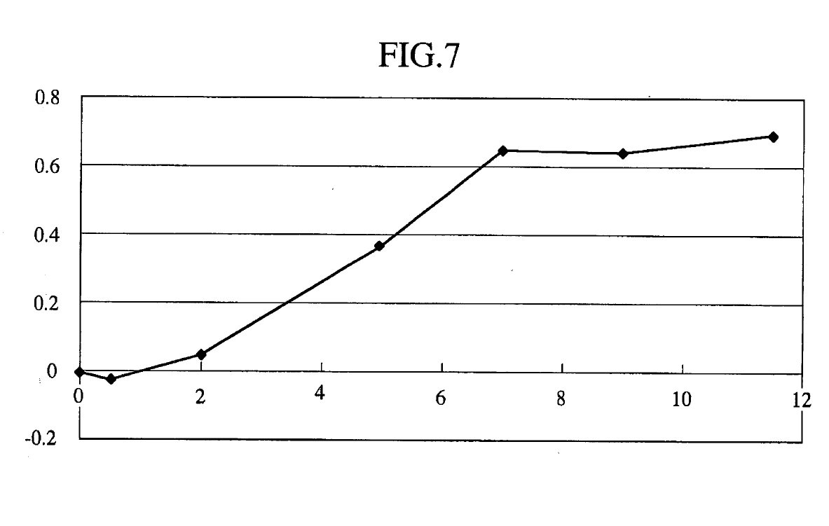

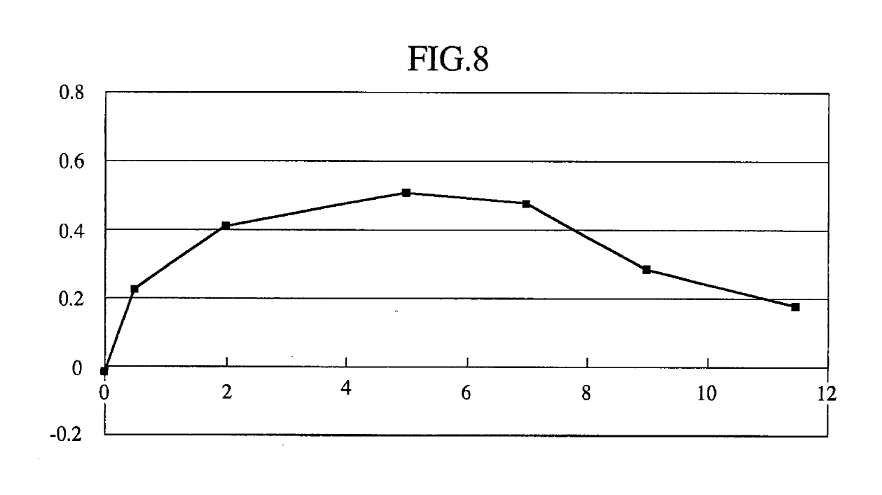

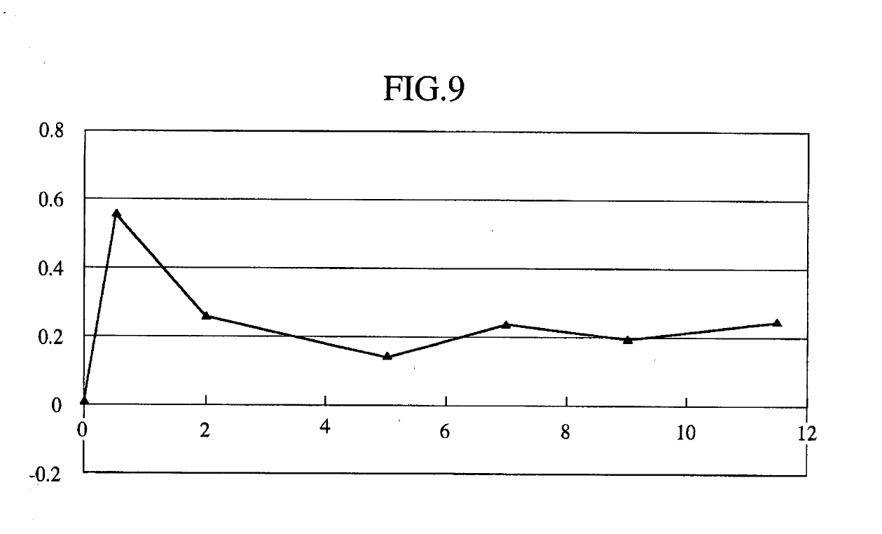

FIG. 5 shows graphs of typical models of expressions of a gene. FIG. 6, FIG. 7, FIG. 8 and FIG. 9 shows graphs respectively representing component change information obtained in accordance with the above method described in the embodiment.

Specifically, FIG. 5 shows graphs of component change information representing average changes in the component of a yeast gene (hereinafter, component change information is timely referred to as “profile”). The horizontal axis of FIG. 5 represents elapsing of time, and the vertical axis thereof represents logarithms of expression ratios. The consideration here concerns the following seven kinds of model profiles, and typical genes belonging to those model profiles (shown after “- - -”).

Metabolic—ACS1, PYC1, SIP4, CAT2, YOR100C, CAR1

Early I—ZIP1, YDR374C, DMC1, HOP1, IME2

Early II—KGD2, AGA2, YPT32, MRD1, SP016, NAB4, YPR192W

Early-Mid—YBL078C, QRI1, PDS1, APC4, KNR4, STU2, YNL013C, EX01

Middle—YSW1, SPR28, SPS2, YLR227C, ORC2, YLL005C, YLL012W

Mid-Late—CDC27, DIT2, DIT1

Late—SPS100, YKL050C, YMR322C, YOR391C

FIG. 6 shows seven vectors in the order of a vector having the largest length (norm) to the next, where each vector represents one of the above seven kinds of component change information. The groups to which the component change information shown in FIG. 6 belong are named G1 to G7 respectively. When comparing FIG. 5 and FIG. 6, it is obvious that the expressions of the gene and the seven kinds of component change information which are the classification results have shapes similar to each other. Especially, G1 and G2 appear to match well ‘Early I’ and ‘Middle’ in FIG. 5. Moreover, a vertical inversion of G5 and ‘Late’ match well. However, having carried out the vertical inversion cannot be distinguished by ICA.

FIGS. 7 to 9 respectively show the three longest vectors separately (G1 to G3), in the order of the longest one to the next.

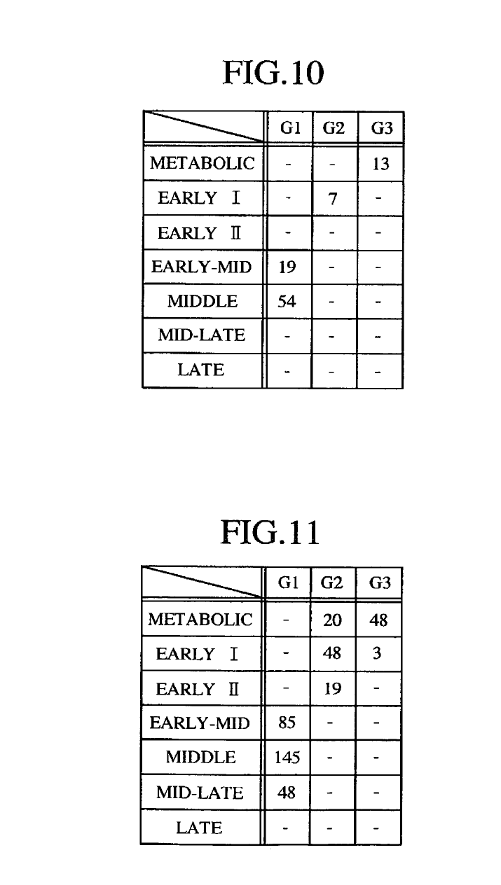

The following explains how each of the above-listed genes is classified based on the yeast gene. FIG. 10 is a table indicating numbers of elements commonly included in each of the groups G1, G2, and G3, and in each of the above seven profiles, where each of the above seven profiles includes 100 genes which are the most analogous with this profile. FIG. 11 is a table indicating numbers of elements commonly included in each of the groups G1, G2, and G3, and in each of the above seven profiles, where each of the above seven profiles includes 200 genes which are the most analogous with this profile.

With reference to FIG. 10 and FIG. 11, it is obvious that component change information on the expressions of the respective genes are classified almost as well as when classified by human labor. Accordingly, the preciseness of this classification method can be proved.

As explained above, according to the present invention, it is possible to provide a chemical substance classification apparatus and a chemical substance classification method suitable for classifying information on changes in a quantity of chemical substances with precision, and a program for realizing those apparatus and method.

Various embodiments and changes may be made thereunto without departing from the broad spirit and scope of the invention. The above-described embodiment is intended to illustrate the present invention, not to limit the scope of the present invention. The scope of the present invention is shown by the attached claims rather than the embodiment. Various modifications made within the meaning of an equivalent of the claims of the invention and within the claims are to be regarded to be in the scope of the present invention.

This application is based on Japanese Patent Application No. 2001-339396 filed on Nov. 5, 2001 and including specification, claims, drawings and summary. The disclosure of the above Japanese Patent Application is incorporated herein by reference in its entirety.

What is claimed is:

1. A chemical substance classification apparatus which classifies plural kinds of information (hereinafter referred to as change information) on changes in a quantity of a plurality of chemical substances (including genes and genetic products), said apparatus comprising:
an information reception unit;
a component analysis unit;
an analogousness degree calculation unit;
and a classification unit,
wherein:
said information reception unit receives plural kinds of change information on changes in a quantity of a plurality of chemical substances as plural kinds of target change information, and supplies the received target change information to said component analysis unit as a target signal group corresponding to the target change information;
said component analysis unit receives the target signal group, analyzes a principal component or independent components of the target signal group in accordance with principal component analysis (PCA) or independent component analysis (ICA), and outputs a component signal group as a result of the analysis;
said analogousness degree calculation unit receives the component signal group output by said component analysis unit as plural kinds of component change information, and calculates analogousness degrees of each of the plural kinds of component change information with respect to each of the plural kinds of target change information; and
said classification unit classifies the plural kinds of target change information into a plurality of classification groups based on the analogousness degrees calculated by said analogousness degree calculation unit.

2. The chemical substance classification apparatus according to claim 1,
wherein:
said information reception unit applies a predetermined conversion to the plural kinds of target change information, and supplies results of the conversion as the target signal group; and
said analogousness degree calculation unit applies a predetermined inversion to the component signal group, and regards results of the inversion as the plural kinds of component change information.

3. A chemical substance classification apparatus which classifies plural kinds of information (hereinafter referred to as change information) on changes in a quantity of a plurality of chemical substances (including genes and genetic products), said apparatus comprising:
a component analysis unit;
an information reception unit;
an analogousness degree calculation unit;
and a classification unit,
wherein:
said component analysis unit receives a target signal group including M(1≦M) kinds of signals x₁(t), x₂(t), . . . , x_{M}(t) (1≦t≦T, t and T are integers), and outputs a matrix W_{k,i} (1≦i≦M, 1≦k≦N) which is obtained when applying independent component analysis (ICA) to a component signal group including N (1≦N≦M) kinds of component signals y₁(t), y₂(t), . . . , y_{N}(t) which are independent components of the target signal group, as a result of the independent component analysis, the matrix W_{k,i} satisfying an equation
$${y}_{k} ( t ) = {\sum }_{i = 1}^{M} {W}_{k , i} {x}_{i} ( t ) ;$$
said information reception unit receives T kinds of change information on changes in a quantity of T kinds of chemical substances (including genes and genetic products) as T kinds of target change information pₜ(i) (where pₜ(i) represents change information of a case where a quantity of a t-th chemical substance changes in accordance with a change in a condition i), and supplies the received T kinds of target change information to said component analysis unit as the target signal group such that xᵢ(t)=pₜ(i) is satisfied;
said analogousness degree calculation unit calculates a pseudo inverse matrix W*_{i,k} of the analysis result W_{k,i} output by said component analysis unit, defines k kinds of component change information qₖ(i) which change in accordance with changes of the condition i, such that qₖ(i)=W*_{i,k} is satisfied, and calculates an analogousness degree between t-th target change information and k-th component change information when measured from an inner product of a M-dimensional vector (pₜ(1), pₜ(2), . . . , pₜ(M)) and a M-dimensional vector (qₖ(1), qₖ(2), . . . , qₖ(M)) which inner product is obtained by normalizing or weighting these vectors, or when measured from an angle formed by these vectors;
said classification unit associates each of the component change information with one of a plurality of classification groups, and classifies the t-th target change information into a classification group associated with component change information with which the t-th target change information is the most analogous by referring to the analogousness degree calculated by said analogousness degree calculation unit.

4. The chemical substance classification apparatus according to claim 3,
wherein said component analysis unit employs principal component analysis (PCA) instead of the independent component analysis.

5. The chemical substance classification apparatus according to claim 3 or 4,
wherein said analogousness degree calculation unit calculates the analogousness degree between the t-th target change information and k-th component change information using yₖ(t), instead of using the inner product of the vectors obtained by normalizing or weighting, or the angle formed by the vectors.

6. The chemical substance classification apparatus according to claim 1 or 3, said apparatus further comprising a labeling unit,
wherein in a case where target change information predetermined for each of the plurality of classification groups is included in the classification group, said labeling unit labels the classification group with a name of a chemical substance corresponding to the predetermined target change information.

7. The chemical substance classification apparatus according to claim 1,
wherein each of the plural kinds of target change information is information representing changes in a density of RNA (including hnRNA, mRNA, and rRNA) which appears as expression of a gene, where the density changes in accordance with an experimental condition.

8. The chemical substance classification apparatus according to claim 1,
wherein each of the plural kinds of target change information is information representing changes in a density of a protein which appears as expression of a gene, where the density changes in accordance with an experimental condition.

9. The chemical substance classification apparatus according to claim 7 or 8,
wherein the experimental condition is lapse of time.

10. A chemical substance classification method of classifying plural kinds of information (hereinafter referred to as change information) on changes in a quantity of a plurality of chemical substances (including genes and genetic products), said method comprising:
an information receiving step;
a component analyzing step;
an analogousness degree calculating step;
and a classifying step,
wherein:
in said information receiving step, plural kinds of change information on changes in a quantity of a plurality of chemical substances are received as plural kinds of target change information, and the plural kinds of target change information are supplied to said component analyzing step as a target signal group corresponding to the plural kinds of target change information;
in said component analyzing step, the target signal group is received, a principal component or independent components of the target signal group is/are analyzed by principal component analysis (PCA) or by independent component analysis (ICA), and a component signal group is output as a result of the analysis;
in said analogousness degree calculating step, the component signal group output in said component analyzing step is received as plural kinds of component change information, and analogousness degrees of each of the plural kinds of component change information with respect to each of the plural kinds of target change information are calculated; and
in said classifying step, the plural kinds of target change information received in said information receiving step are classified into a plurality of classification groups, based on the analogousness degrees calculated in said analogousness degree calculating step.

11. The chemical substance classification method according to claim 10,
wherein:
in said information receiving step, a predetermined conversion is applied to the plural kinds of target change information, and results of the conversion are supplied as the target signal group; and
in said analogousness degree calculating step, a predetermined inversion is applied to the component signal group, and results of the inversion are regarded as the plural kinds of component change information.

12. A chemical substance classification method of classifying a plural kinds of information (hereinafter referred to as change information) on changes in a quantity of a plurality of chemical substances (including genes and genetic products), said method comprising: a component analyzing step; an information receiving step; an analogousness degree calculating step; and a classifying step,
wherein:
in said component analyzing step, a target signal group including M (1≦M) kinds of signals x₁(t), x₂(t), . . . , x_{M}(t) (1≦t≦T, t and T are integers) is received, and a matrix W_{k,i} (1≦i≦M, 1≦k≦N), which is obtained when applying independent component analysis (ICA) to a component signal group including N (1≦N<M) kinds of component signals y₁(t), y₂(t), . . . , y_{N}(t) which are independent components of the target signal group, is output as a result of the independent component analysis, the matrix W_{k,i} satisfying an equation
$${y}_{k} ( t ) = {\sum }_{i = 1}^{M} {W}_{k , i} {x}_{i} ( t ) ;$$
in said information receiving step, T kinds of change information on changes in a quantity of T kinds of chemical substances (including genes and genetic products) are received as T kinds of target change information pₜ(i) (where pₜ(i) represents change information of a case where a quantity of a t-th chemical substance changes in accordance with changes in a condition i), and the T kinds of target change information pₜ(i) are supplied to said component analyzing step as the target signal group, such that xᵢ(t)=pₜ(i) is satisfied;
in said analogousness degree calculating step, a pseudo inverse matrix W*_{i,k} of the analysis result W_{k,i} output in said component analyzing step is calculated, k kinds of component change information qₖ(i) which change in accordance with changes in the condition i are defined such that qₖ(i)=W*_{i,k} is satisfied, and an analogousness degree between t-th target change information and k-th component change information when measured from an inner product of a M-dimensional vector (pₜ(1), pₜ(2), . . . , pₜ(M)) and a M-dimensional vector (qₖ(1), qₖ(2), . . . , qₖ(M)) which inner product is obtained by normalizing or weighting these vectors, or when measured from an angle formed by theses vectors is calculated; and
in said classifying step, each of the component change information is associated with one of a plurality of classification groups, and the t-th target change information is classified into a classification group associated with component change information with which the t-th target change information is the most analogous by referring to the analogousness degree calculated in said analogousness degree calculating step.

13. The chemical substance classification method according to claim 12,
wherein in said component analyzing step, principal component analysis (PCA) is employed instead of the independent component analysis.

14. The chemical substance classification method according to claim 12 or 13,
wherein in said analogousness degree calculating step, the analogousness degree between the t-th target change information and the k-th component change information is calculated using yₖ(t), instead of using the inner product obtained by normalizing or weighting the vectors or the angle formed by the vectors.

15. The chemical substance classification method according to claim 10 or 12, further comprising a labeling step,
wherein in said labeling step, in a case where target change information predetermined for each of the plurality of classification groups is included in the classification group, the classification group is labeled with a name of a chemical substance corresponding to the predetermined target change information.

16. The chemical substance classification method according to claim 10,
wherein each of the plural kinds of target change information is information representing changes in a density of RNA (including hnRNA, mRNA, and rRNA) which appears as expression of a gene, where the density changes in accordance with an experimental condition.

17. The chemical substance classification method according to claim 10,
wherein each of the plural kinds of target change information is information representing changes in a density of a protein which appears as expression of a gene, where the density changes in accordance with an experimental condition.

18. The chemical substance classification method according to claim 16 or 17,
wherein the experimental condition is lapse of time.

19. A program for controlling a computer to function as a chemical substance classification apparatus described in claim 1 or 3.

20. A program for controlling a computer to execute a chemical substance classification method described in claim 10 or 12.
